(19) United States
(12) Patent Application Publication
(10) Pub. No.: US 2023/0253322 A1
(43) Pub. Date: Aug. 10, 2023

(54) NANO-TSV LANDING OVER BURIED POWER RAIL

(71) Applicant: INTERNATIONAL BUSINESS MACHINES CORPORATION, ARMONK, NY (US)

(72) Inventors: Kisik Choi, Watervliet, NY (US); Ruilong Xie, Niskayuna, NY (US); FEE LI LIE, Albany, NY (US); SOMNATH GHOSH, CLIFTON PARK, NY (US); Theodorus E. Standaert, Clifton Park, NY (US)

(21) Appl. No.: 17/650,385

(22) Filed: Feb. 9, 2022

(51) Int. Cl. H01L 23/528; H01L 27/092; H01L 23/48; H01L 21/768; H01L 21/8238

(52) U.S. Cl. CPC H01L 23/5286; H01L 27/0924; H01L 23/481; H01L 21/76898; H01L 21/823871; H01L 21/823878; H01L 21/823821

(57) ABSTRACT

Embodiments of present invention provide a semiconductor structure. The semiconductor structure includes a substrate layer; and a buried power rail (BPR) embedded in the substrate layer, wherein the BPR is isolated from the substrate layer by an enlarged deep shallow-trench-isolation (STI) region. In one embodiment, the enlarged deep STI region has a first width at near a top thereof and a second width at near a middle portion thereof, with the second width being larger than the first width. A method of making the above semiconductor structure is also provided.

### FIELD OF THE INVENTION

The present application relates to manufacturing of semiconductor integrated circuits. More particularly, it relates to a semiconductor structure for landing nano-TSV over buried power rail and method of manufacturing the same.

### BACKGROUND

With the continuous pursuit for the reduction in size of semiconductor circuitry, it becomes increasingly difficult to physically align semiconductor devices in and/or at various integration levels. One such example includes the integration of buried power rails in a semiconductor substrate.

At current transistor node level, the critical dimension (CD) of buried power rail has become extremely small. In a process of forming nano through-silicon-via to land on the buried power rail, a bad or poor CD or overlay control may cause the nano through-silicon-via to be shorted to the substrate which normally directly surrounds the buried power rails.

### SUMMARY

Embodiments of present invention provide a semiconductor structure. The semiconductor structure includes a substrate layer; and a buried power rail (BPR) embedded in the substrate layer, wherein the BPR is isolated from the substrate layer by an enlarged deep shallow-trench-isolation (STI) region. According to one embodiment, the enlarged deep STI region has a first width at near a top thereof and a second width at near a middle portion thereof, with the second width being larger than the first width.

In one embodiment, the semiconductor structure further includes a nano through-silicon via (nTSV), with a bottom portion of the nTSV contacting a bottom portion of the BPR, where the bottom portion of the nTSV is fully surrounded by the enlarged deep STI region.

In another embodiment, the nTSV is embedded in the substrate layer and sidewalls of the TSV are fully surrounded by and isolated from the substrate layer by the enlarged deep STI region.

Embodiments of present invention also provide a method of forming a semiconductor structure. In one embodiment, the method includes providing a semiconductor substrate; forming first recesses in the semiconductor substrate; deepening and laterally widening the first recesses to form enlarged deep STI regions; filling the enlarged deep STI regions with a dielectric material; and forming at least one buried power rail (BPR) inside the dielectric material in the enlarged deep STI regions.

In one embodiment, the method further includes flipping the semiconductor substrate upside down and forming a nano through-silicon via (nTSV) through at least a portion of the semiconductor substrate, wherein the nTSV contacts the at least one BPR.

In another embodiment, forming the nTSV further includes thinning down the semiconductor substrate to create a substrate layer and depositing an inter-level-dielectric (ILD) layer on top of the substrate layer.

In yet another embodiment, forming the nTSV further includes forming an nTSV opening through the ILD layer and the substrate layer to expose a bottom portion of the at least one BPR, via a patterning process, and filling the nTSV opening with one or more conductive materials to form the nTSV.

### BRIEF DESCRIPTION OF THE DRAWINGS

The present invention will be understood and appreciated more fully from the following detailed description of embodiments of present invention, taken in conjunction with accompanying drawings of which:

FIGS. 1-14 are demonstrative illustrations of cross-sectional views of a semiconductor structure during a process of a method of manufacturing thereof according to embodiments of present invention; and

FIG. 15 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity or they are embodied in a single physical entity.

### DETAILED DESCRIPTION OF PREFERRED EMBODIMENTS

In the below detailed description and the accompanying drawings, it is to be understood that various layers, structures, and regions shown in the drawings are both demonstrative and schematic illustrations that are not drawn to scale. In addition, for the ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the drawings to denote the same or similar features, elements, or structures, and thus, a detailed explanation of the same or similar features, elements, or structures may not be repeated for each of the drawings. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

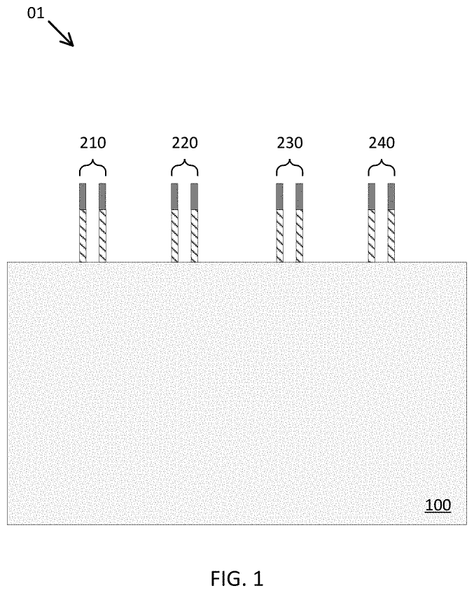

FIG. 1 is a demonstrative illustration of cross-sectional view of a semiconductor structure during a process of a method of manufacturing thereof according to one embodiment of present invention. More specifically, FIG. 1 illustrates a semiconductor structure 01 that includes a semiconductor substrate 100, and a plurality of sets of fins on top of semiconductor substrate 100. Semiconductor substrate 100 may be a bulk silicon (Si) substrate, a bulk germanium (Ge) substrate, a silicon-on-insulator (SOI) substrate, a silicon-germanium-on-insulator (SiGeOI) substrate, or any other suitable substrates.

The plurality of sets of fins may include multiple sets of fins and in this application a set of fins may include one or more fins. A set of fins may be created to make one type of field-effect-transistors (FETs) such as, for example, a p-type FET or an n-type FET. Hereinafter, a set of fins may be referred to a fin-set, and a set of fins that is created to make a p-type FET may be referred to as a PFET fin-set and a set of fins that is created to make an n-type FET may be referred to as an NFET fin-set.

As is illustrated in FIG. 1, semiconductor structure 01 may include a first fin-set 210, a second fin-set 220, a third fin-set 230, and a fourth fin-set 240. According to an embodiment, first fin-set 210 may be an NFET fin-set, second fin-set 220 may be a PFET fin-set, third fin-set 230 may be a PFET fin-set, and fourth fin-set 240 may be an NFET fin-set. Although not illustrated in FIG. 1, it is further assumed here that there may be an NFET fin-set to the left of first fin-set 210 and an NFET fin-set to the right of fourth fin-set 240 as well.

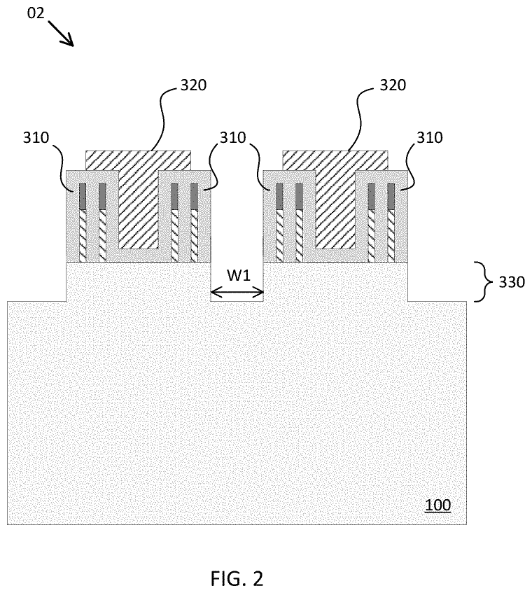

FIG. 2 is a demonstrative illustration of cross-sectional view of a semiconductor structure during a process of a method of manufacturing thereof according to one embodiment of present invention. More specifically, FIG. 2 illustrates a semiconductor structure 02 after forming a fin protecting liner 310 such as, for example, an oxide liner covering first, second, third, and fourth fin-set 210, 220, 230, and 240. In one embodiment, liner 310 may be a conformal liner and gaps between fins within a fin-set may be filled up by liner 310. The embodiment also includes applying a mask layer 320, such as an organic planarization layer (OPL), to cover and protect spaces between fin-sets for different types of FETs, while leave spaces open or uncovered between fin-sets for the same type of FETs. For example, the embodiment may include applying mask layer 320 to cover and protect spaces between first fin-set 210 and second fin-set 220 and between third fin-set 230 and fourth fin-set 240 and leave the space between second fin-set 220 and third fin-set 230, the space left to first fin-set 210, and the space right to fourth fin-set 240, uncovered. The embodiment further includes etching semiconductor substrate 100 to create a first recesses 330. First recesses 330 may be etched to have a depth around 20 to 80 nm such that sufficient areas directly underneath fin-sets may be preserved for the formation and functioning of transistors, and not be affected by later process of forming buried power rails. First recesses 330 may have a first width W1.

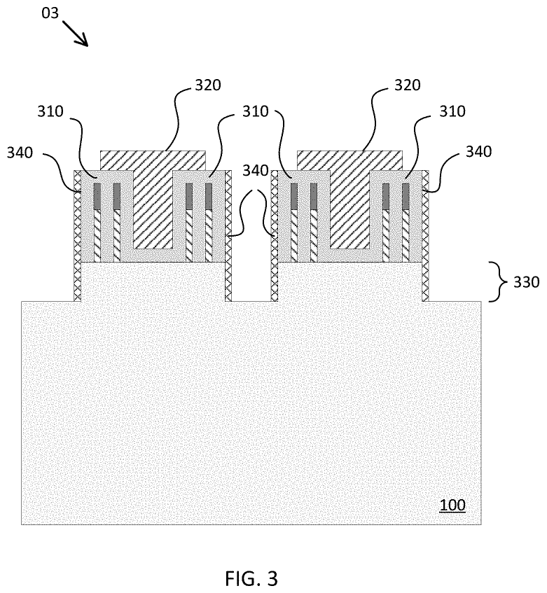

FIG. 3 is a demonstrative illustration of cross-sectional view of a semiconductor structure during a process of a method of manufacturing thereof according to one embodiment of present invention. More specifically, FIG. 3 illustrates a semiconductor structure 03 and one embodiment of the method includes forming additional liners 340 next to sidewalls of first recesses 330, thereby protecting the sidewalls of first recesses 330 from subsequent etching process. Liners 340 may be, for example, low temperature silicon-nitride (SiN) liner. However embodiment of present invention is not limited in this aspect and other materials of liners may be used as well.

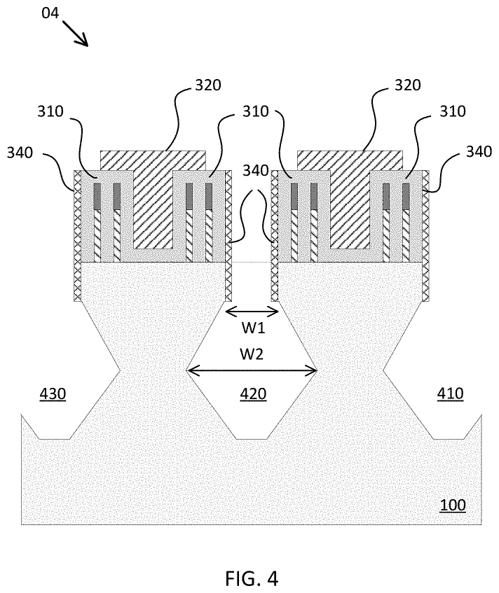

FIG. 4 is a demonstrative illustration of cross-sectional view of a semiconductor structure during a process of a method of manufacturing thereof according to one embodiment of present invention. More specifically, FIG. 4 illustrates a semiconductor structure 04 and one embodiment of the method includes performing etching further into semiconductor substrate 100 to deepen and widen first recesses 330 to create enlarged openings 410, 420, and 430 for forming enlarged deep STI regions in a later stage. For example, performing etching may include not only etching deep into semiconductor substrate 100 but also widening the etching in a horizontal direction, from the first width W1 of first recesses 330 (less the thickness of liner 340) to a second width W2 of enlarged openings 410, 420, and 430 with W2 being larger than W1, such that enlarged deep STI regions may be formed later. In one embodiment, anisotropic dry etching may be performed using, for example, HBr, Cl₂, He, followed with an isotropic wet etch with tetramethylammonium hydroxide (TMAH) to form the openings, and based on the type of etchants used and crystalline orientation of semiconductor substrate 100, enlarged openings 410, 420, and 430 may be in a sigma shape, in a diamond shape, or in a hexagon shape. The horizontal widening may go beyond liners 340 into regions underneath the fin-sets such as, for example, underneath second fin-set 220 and third fin-set 230. The enlarged openings 410, 420, and 430 may have the second width W2 at near the middle portion thereof larger than the first width W1 at near the top thereof that is near the top of semiconductor substrate 100.

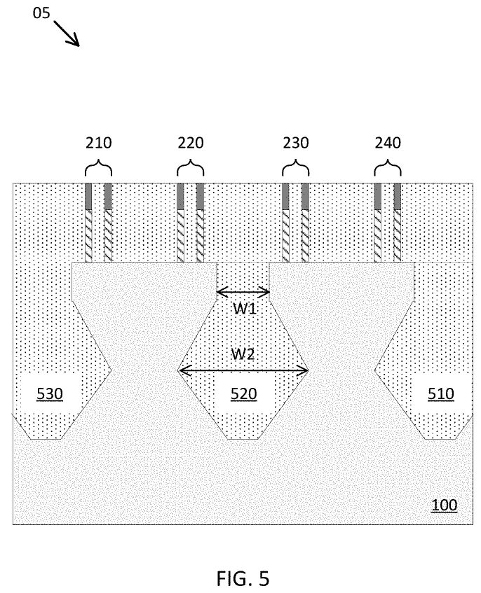

FIG. 5 is a demonstrative illustration of cross-sectional view of a semiconductor structure during a process of a method of manufacturing thereof according to one embodiment of present invention. More specifically, FIG. 5 illustrates a semiconductor structure 05 and one embodiment of the method includes selectively removing liners 340 that cover the sidewalls of first recesses 330, removing mask layer 320 between first fin-set 210 and second fin-set 220 and between third fin-set 230 and fourth fin-set 240, and removing liners 310 that cover first, second, third, and fourth fin-set 210, 220, 230, and 240 based on etch selectivity of respective materials to used etchants. The embodiment further includes subsequently filling enlarged openings 410, 420, and 430 with a dielectric material such as, for example, flowable oxide to create enlarged deep STI regions 510, 520, and 530. The flowable oxide may be deposited through a chemical vapor deposition (CVD) process, followed by a steam annealing process, to fill the re-entrant shape of the openings. In doing so, enlarged deep STI regions 510, 520, and 530 may have a first width W1 at near a top thereof and a second width at near the middle portion thereof and the second width W2 is larger than the first width W1.

Here, it is to be noted that other suitable dielectric materials, in addition to flowable oxide, may be used as well in forming the enlarged deep STI regions 510, 520, and 530. The dielectric material may be filled into the enlarged openings 410, 420, and 430, in spaces between the sidewalls of first recesses 330 previously covered by liners 340, and in spaces between and above first fin-set 210, second fin-set 220, third fin-set 230, and fourth fin-set 240. Embodiment then applies a chemical-mechanic-polishing (CMP) process to remove excessive dielectric material above the fins to polish down, for example, to the top of the fin hardmask.

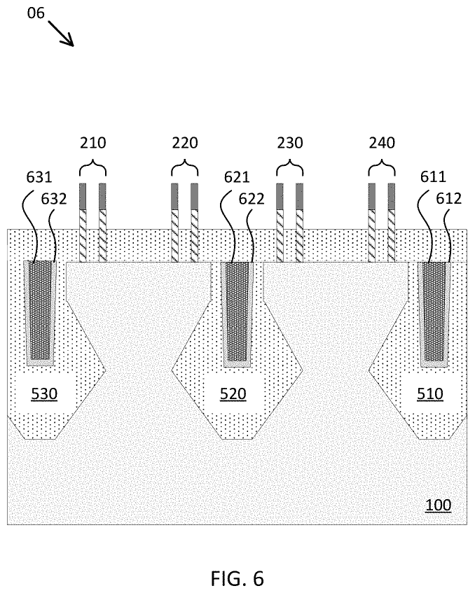

FIG. 6 is a demonstrative illustration of cross-sectional view of a semiconductor structure during a process of a method of manufacturing thereof according to one embodiment of present invention. More specifically, FIG. 6 illustrates a semiconductor structure 06 and one embodiment of the method includes forming buried power rail trenches, filling the buried power rail trenches with metals, recessing the buried power rail metals, overfilling the recess with a dielectric, planarizing the dielectric, and recessing the dielectric to reveal the fins with buried power rail still being covered by the dielectric.

More specifically, using lithographic patterning process, buried power rail trenches may be made inside enlarged deep STI regions 510, 520, and 530 and the trenches may be subsequently filled with one or more conductive materials, such as tungsten (W), cobalt (Co), ruthenium (Ru), and/or copper (Cu) (with a thin adhesive metal liner, such as TiN), to form buried power rails 611, 621, and 631. According to embodiments of present invention, the trenches (for forming buried power rails) may be created entirely inside enlarged deep STI regions 510, 520, and 530 and there is no part of the trenches that open directly to semiconductor substrate 100. Thereafter, a dielectric liner such as, for example, a SiN liner may be optionally formed inside the trenches first before one or more conductive materials are used to fill up the openings to form buried power rails. For example, liners 612, 622, 632 may be formed lining the bottoms and sidewalls of the trenches and then metals, such as W, Co, Ru, and/or Cu with a thin adhesive metal liner such as TiN, may be used to fill the remaining trenches to form buried power rails 611, 621, and 631. However, since buried power rails 611, 621, and 631 are now surrounded by dielectric materials of enlarged deep STI regions 510, 520, and 530, liners 612, 622, and 632 may not be necessary. After the metal fill, the metals may be recessed, followed by dielectric overfill, planarization of the dielectric, and recess of the dielectric to reveal the active fins for further device fabrication.

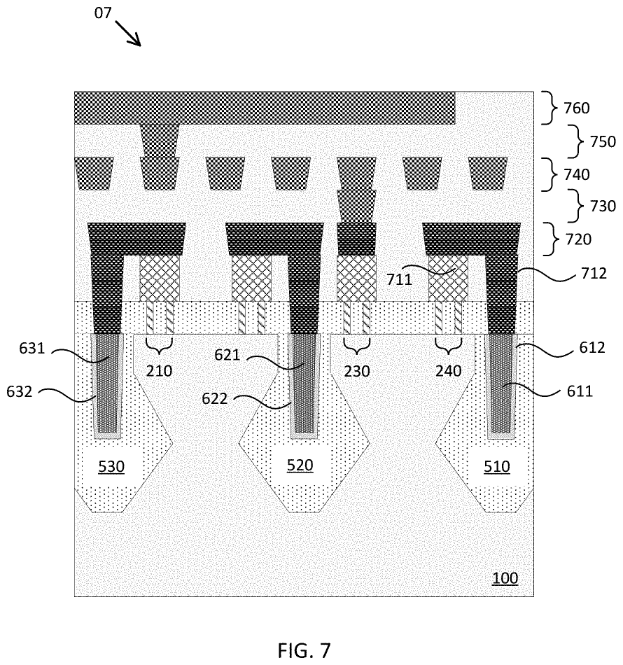

FIG. 7 is a demonstrative illustration of cross-sectional view of a semiconductor structure during a process of a method of manufacturing thereof according to one embodiment of present invention. More specifically, FIG. 7 illustrates a semiconductor structure 07 and one embodiment of the method includes, after forming buried power rails 611, 621, and 631, forming transistors such as NFETs and PFETs using the plurality of sets of fins by forming gates (not shown) and source/drain regions 711, forming one or more via-to-BPR contact (VBPR) 712, and forming source/drain contact layer 720 which may be a middle-of-line (MOL) layer. One or more back-end-of-line (BEOL) layers such as BEOL layers 730/740 and 750/760 may be subsequently formed on top of MOL layer 720.

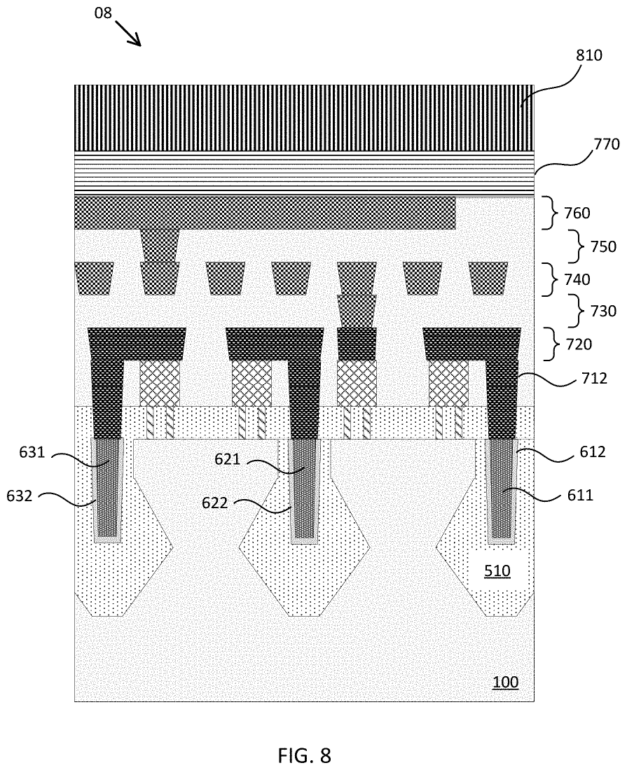

FIG. 8 is a demonstrative illustration of cross-sectional view of a semiconductor structure during a process of a method of manufacturing thereof according to one embodiment of present invention. More specifically, FIG. 8 illustrates a semiconductor structure 08 and one embodiment of the method includes forming additional BEOL layers 770 on top of BEOL layer 760, and subsequently wafer bonding a carrier wafer 810 on top of BEOL layers 770. Carrier wafer 810 may be bonded to semiconductor structure 08, for the ease of handling, such that semiconductor substrate 100 may be flipped upside down for further processing from the bottom of semiconductor substrate 100.

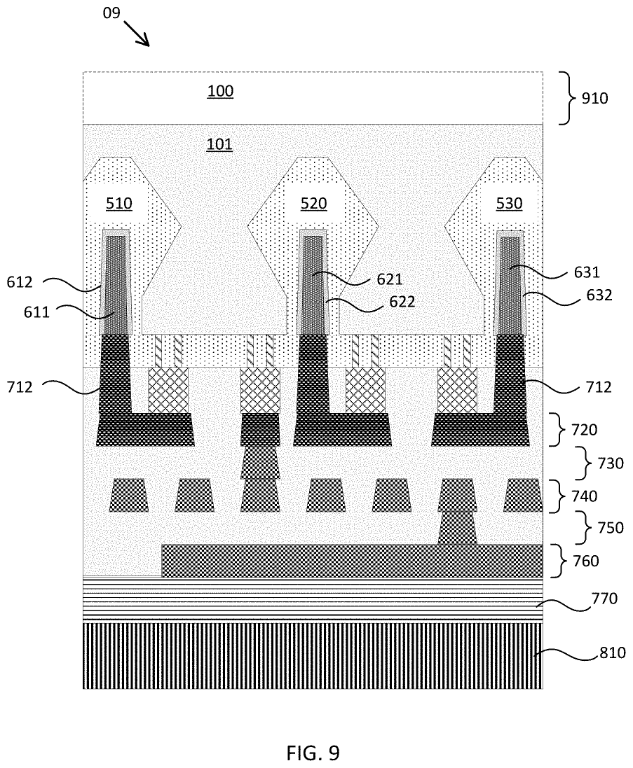

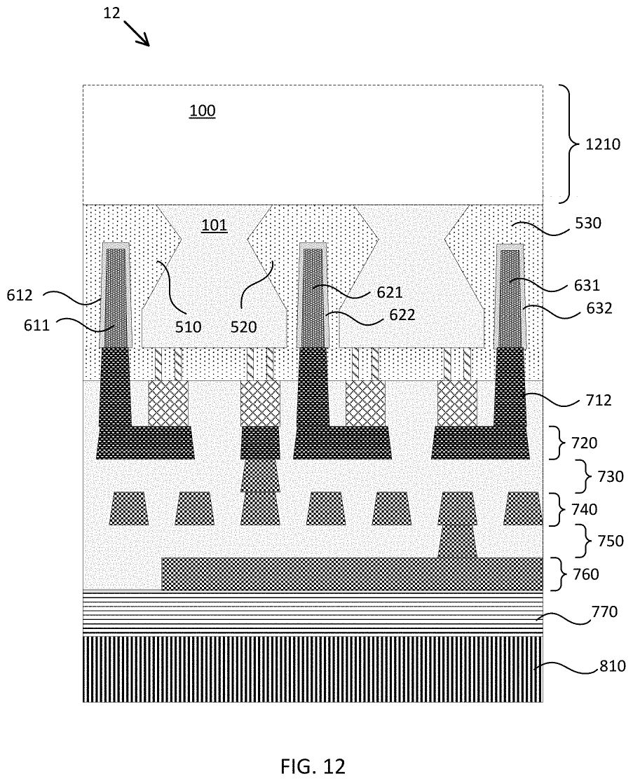

FIG. 9 is a demonstrative illustration of cross-sectional view of a semiconductor structure during a process of a method of manufacturing thereof according to one embodiment of present invention. More specifically, FIG. 9 illustrates a semiconductor structure 09 which is an upside-down flipped semiconductor structure 08 illustrated in FIG. 8. After flipping the semiconductor structure 08, one embodiment of the method includes thinning down, such as through grinding, CMP, or other etching processes, semiconductor substrate 100 by a thickness 910 to create a substrate layer 101. In one embodiment as being illustrated in FIG. 9, the thinning down process may not expose a top surface of the enlarged deep STI regions 510, 520, and 530. However, embodiment of present invention may include thinning down semiconductor substrate 100 to expose a top surface of or even into the enlarged deep STI regions 510, 520, and 530, as being described below in more details with reference to FIG. 12.

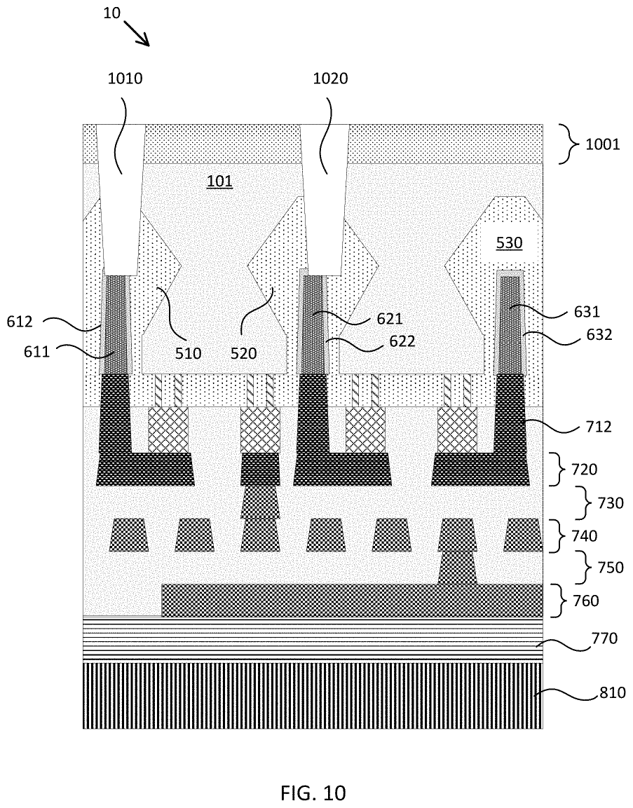

FIG. 10 is a demonstrative illustration of cross-sectional view of a semiconductor structure during a process of a method of manufacturing thereof according to one embodiment of present invention. More specifically, FIG. 10 illustrates a semiconductor structure 10 and one embodiment of the method includes depositing an inter-level dielectric (ILD) layer 1001 on top of the thinned down semiconductor substrate otherwise referred to herein as substrate layer 101. The embodiment then includes performing a lithographic patterning process to create openings such as openings 1010 and 1020 for forming through-silicon-vias (TSVs). TSVs may have different sizes in diameter and in one embodiment the diameter of TSVs may be in the range of 15 to 120 nanometers. Such TSVs may be referred to as nano TSVs (nTSVs). Embodiments of present invention may create openings 1010 and 1020 for forming TSVs in general and in one embodiment for forming nTSVs.

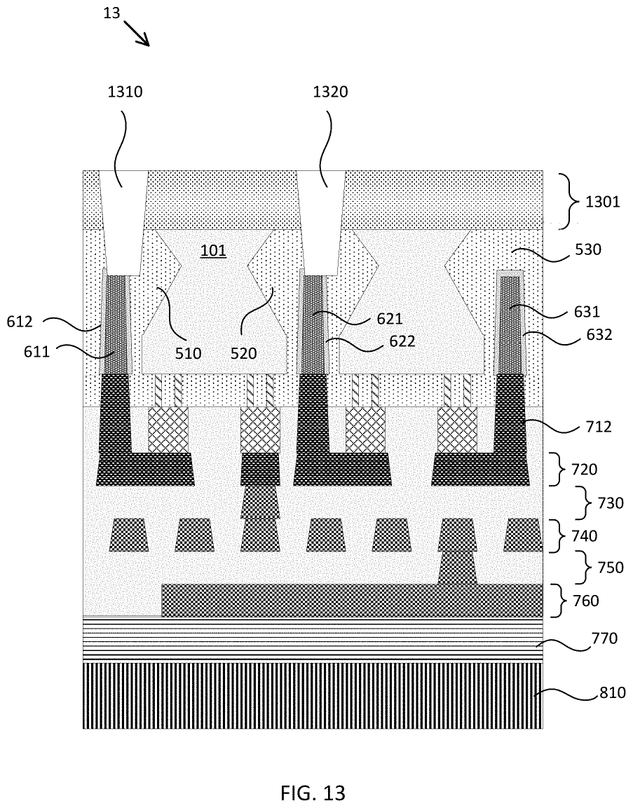

According to one embodiment of present invention, at least a bottom portion and a lower portion of openings 1010 and 1020 may be created entirely inside enlarged deep STI regions 510 and 520. However, embodiments of present invention are not limited in this aspect and in one embodiment, as being described below in more details with reference to FIG. 13, sidewalls of openings 1310 and 1320 may be entirely surrounded by the enlarged deep STI regions 510 and 520. In FIG. 10, as a non-limiting example, it is assumed that no opening (for forming TSV) is created in enlarged deep STI region 530.

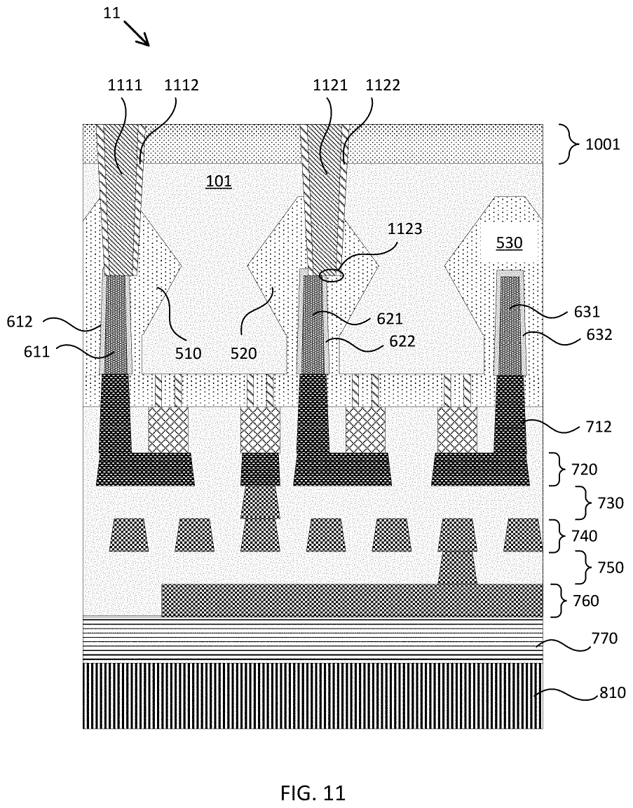

FIG. 11 is a demonstrative illustration of cross-sectional view of a semiconductor structure during a process of a method of manufacturing thereof according to one embodiment of present invention. More specifically, FIG. 11 illustrates a semiconductor structure 11 and one embodiment of the method includes forming liners 1112 and 1122 of dielectric material, such as SiN, lining openings 1010 and 1020. At the bottom of openings 1010 and 1020, horizontal portions of the liner material of liner 1112 and 1122 may be subsequently removed by an anisotropic etch to expose a bottom portion of BPR 611 and BPR 621 for contact purpose. Conductive material such as, for example, W, Co, Ru, or Cu may then be used to fill openings 1010 and 1020 to form TSVs and more particularly nTSVs 1111 and 1121. A bottom portion of nTSVs 1111 and 1112 contacts directly, at least partially, a bottom portion of BPR 612 and BPR 622.

Here it is to be noted that because at least a bottom portion of openings 1010 and 1020 are created entirely inside enlarged deep STI regions 510 and 520, a misalignment between, for example, BPR 621 and nTSV 1121 may cause a part 1123 of the bottom portion of nTSV 1121 to be exposed to enlarged deep STI region 520. Since enlarged deep STI region 520 is made of dielectric material such as flowable oxide, the misaligned part 1123 of the bottom portion of nTSV 1121 is still isolated from substrate layer 101.

FIG. 12 is a demonstrative illustration of cross-sectional view of a semiconductor structure during a process of a method of manufacturing thereof according to another embodiment of present invention. More specifically, FIG. 12 illustrates a semiconductor structure 12 following the step illustrated in FIG. 8. More particularly, one embodiment of the method includes flipping the semiconductor structure 08 in FIG. 08 upside down and performing a thinning process to semiconductor substrate 100 to remove a thickness 1210 thereof, which is relatively thicker than that of thickness 910 illustrated in FIG. 9, resulting in a thinner substrate layer 101. The removal of the thickness 1210 of semiconductor substrate 100 ensures that nTSVs formed in subsequent process steps to contact the BPRs are entirely surrounded by enlarged deep STI regions that are embedded in substrate layer 101.

FIG. 13 is a demonstrative illustration of cross-sectional view of a semiconductor structure during a process of a method of manufacturing thereof according to one embodiment of present invention. More specifically, FIG. 13 illustrates a semiconductor structure 13 and one embodiment of the method includes forming an ILD layer 1301 on top of substrate layer 101, and lithographically patterning one or more openings 1310 and 1320 for forming TSVs such as nTSVs. It is to be noted here that openings 1310 and 1320, at least for the portions that are inside substrate layer 101, are entirely surrounded by enlarged deep STI regions 510 and 520.

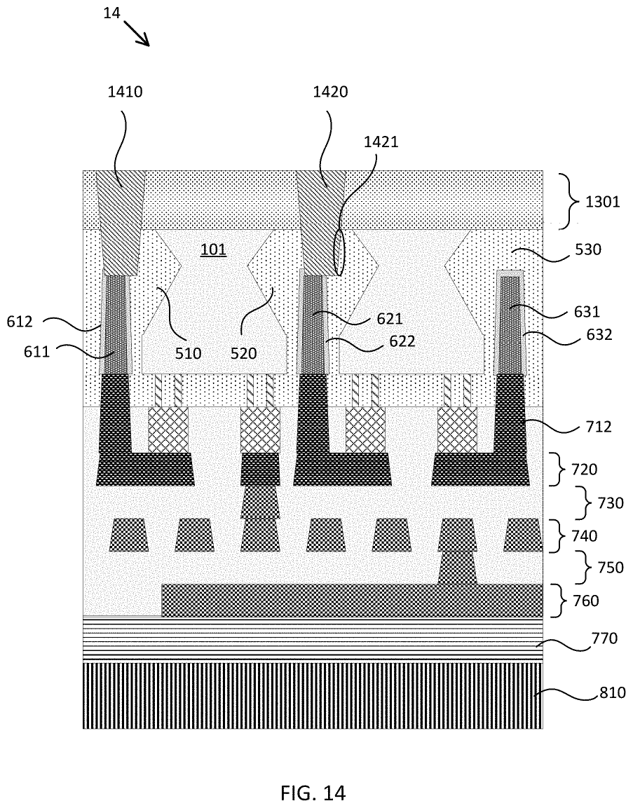

FIG. 14 is a demonstrative illustration of cross-sectional view of a semiconductor structure during a process of a method of manufacturing thereof according to one embodiment of present invention. More specifically, FIG. 14 illustrates a semiconductor structure 14 and one embodiment of the method includes performing metallization by filling openings 1310 and 1320 with one or more conductive materials such as, W, Co, Ru, and/or Cu, to form TSVs such as nTSVs 1410 and 1420. Contrast to nTSVs 1111 and 1121 illustrated in FIG. 11, since openings 1310 and 1320 are embedded in substrate layer 101 but separated and isolated from substrate layer 101 by enlarged deep STI regions 510 and 520, no dielectric liner such as SiN liner is needed to prevent nTSVs 1410 and 1420 from contacting or shorting substrate layer 101. For example, according to embodiment of present invention, when nTSV 1420 is misaligned with BPR 621, as an illustrative example shown in FIG. 14, a bottom of nTSV 1420 is covered by enlarged deep STI region 520. In the meantime, since sidewalls 1421 of nTSV 1420 are fully surrounded by enlarged deep STI region 520 as well, they are prevented from shorting or contacting substrate layer 101.

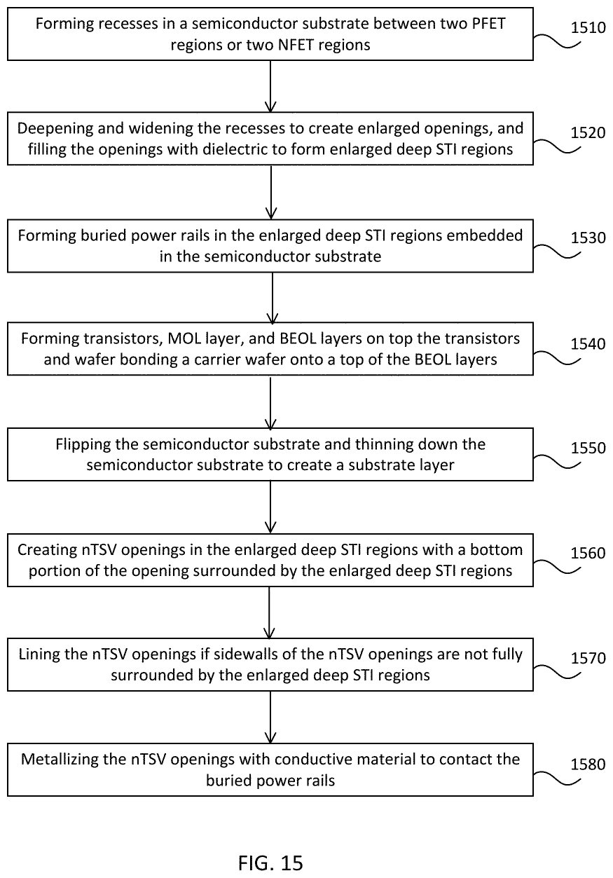

FIG. 15 is a demonstrative illustration of a flow-chart of a method of manufacturing a semiconductor structure according to embodiments of present invention. The embodiment includes (1510) forming first recesses in a semiconductor substrate between semiconductor device regions such as between two NFET regions or between two PFET regions; (1520) deepening and widening the first recesses to create enlarged openings and subsequently filling the enlarged openings with a dielectric material to form enlarged deep STI regions; (1530) forming buried power rails in the enlarged deep STI regions embedded in the semiconductor substrate; and (1540) forming transistors such as NFETs and PFETs and associated MOL layer and BEOL layers on top the transistors and wafer bonding a carrier wafer onto a top of the BEOL layers.

Embodiments of present invention further include (1550) flipping the semiconductor substrate upside down and thinning down a thickness of the semiconductor substrate to create a substrate layer with the thinning process, in one embodiment, exposing the enlarged deep STI regions; (1560) creating nano through-silicon-via (nTSV) openings in the enlarged deep STI regions with at least a bottom portion of the openings being surrounded by the enlarged deep STI regions. This nTSV creation process may be made by first depositing an inter-level-dielectric (ILD) layer on top of the substrate layer, planarizing the ILD layer, and patterning the nTSV openings through a lithographic patterning and etching process. In one embodiment, sidewalls of the nTSV openings are not fully surrounded by the enlarged deep STI regions, and the embodiment may include (1570) lining the nTSV openings with a dielectric liner. Embodiments of present invention may further include (1580) metallizing the nTSV openings with conductive material to contact the buried power rails.

It is to be understood that the exemplary methods discussed herein for fabricating or manufacturing strained superlattice may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Although exemplary embodiments have been described herein with reference to the accompanying figures, it is to be understood that the invention is not limited to those precise embodiments, and that various other changes and modifications may be made therein by one skilled in the art without departing from the scope of the appended claims.

It is to be understood that the various layers, structures, and/or regions described above are not necessarily drawn to scale. In addition, for ease of explanation one or more layers, structures, and regions of a type commonly used to form semiconductor devices or structures may not be explicitly shown in a given illustration or drawing. This does not imply that any layers, structures, and regions not explicitly shown are omitted from the actual semiconductor structures.

Furthermore, it is to be understood that the embodiments discussed herein are not limited to the particular processing steps shown and described herein. In particular, with respect to semiconductor processing steps, it is to be emphasized that the descriptions provided herein are not intended to encompass all of the processing steps that may be used to form a functional semiconductor integrated circuit device. Rather, certain processing steps that are commonly used in forming semiconductor devices, such as, for example, wet cleaning and annealing steps, are purposefully not described herein for economy of description.

Terms such as “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Also, in the figures, the illustrated scale of one layer, structure, and/or region relative to another layer, structure, and/or region is not necessarily intended to represent actual scale.

Semiconductor devices and methods for forming same in accordance with the above-described techniques can be employed in various applications, hardware, and/or electronic systems, including but not limited to personal computers, communication networks, electronic commerce systems, portable communications devices (e.g., cell and smart phones), solid-state media storage devices, functional circuitry, etc. Given the teachings provided herein, one of ordinary skill in the art will be able to contemplate other implementations and applications of embodiments of the invention.

In some embodiments, the above-described techniques are used in connection with manufacture of semiconductor integrated circuit devices that illustratively include, by way of non-limiting example, CMOS devices, MOSFET devices, and/or FinFET devices, and/or other types of semiconductor integrated circuit devices that incorporate or otherwise utilize CMOS, MOSFET, and/or FinFET technology.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other higher level carrier) or in a multichip package (such as a ceramic carrier that has either or both surface interconnections or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While certain features of the invention have been illustrated and described herein, many modifications, substitutions, changes, and equivalents will now occur to those of ordinary skill in the art. Such changes, modification, and/or alternative embodiments may be made without departing from the spirit of present invention and are hereby all considered within the scope of present invention. It is, therefore, to be understood that the appended claims are intended to cover all such modifications and changes as fall within the spirit of the invention.

What is claimed is:

1. A semiconductor structure comprising:
a substrate layer; and
a buried power rail (BPR) embedded in an enlarged deep shallow-trench-isolation (STI) region inside the substrate layer,
wherein the BPR is isolated from the substrate layer by the enlarged deep STI region.

2. The semiconductor structure of claim 1, further comprising a nano through-silicon via (nTSV), a bottom portion of the nTSV contacting a bottom portion of the BPR, wherein the bottom portion of the nTSV is fully surrounded by the enlarged deep STI region.

3. The semiconductor structure of claim 2, wherein the nTSV is embedded in the substrate layer, and sidewalls of the nTSV are fully surrounded by and isolated from the substrate layer by the enlarged deep STI region.

4. The semiconductor structure of claim 2, wherein the nTSV comprises a conductive material that is in direct contact with the enlarged deep STI region at sidewalls of the nTSV.

5. The semiconductor structure of claim 2, wherein the nTSV is misaligned with the BPR, a first part of the bottom portion of the nTSV contacts the bottom portion of the BPR, and a second part of the bottom portion of the nTSV is covered by the enlarged deep STI region.

6. The semiconductor structure of claim 1, wherein the enlarged deep STI region has a first width at near a top thereof and a second width at near a middle portion thereof, wherein the second width being larger than the first width.

7. A method of forming a semiconductor structure comprising:
providing a semiconductor substrate;
forming first recesses in the semiconductor substrate;
deepening and laterally widening the first recesses to form enlarged deep STI regions;
filling the enlarged deep STI regions with a dielectric material; and
forming at least one buried power rail (BPR) inside the dielectric material in the enlarged deep STI regions.

8. The method of claim 7, further comprising flipping the semiconductor substrate upside down and forming a nano through-silicon via (nTSV) through at least a portion of the semiconductor substrate, the nTSV contacting the at least one BPR.

9. The method of claim 8, wherein forming the nTSV further comprises thinning down the semiconductor substrate to create a substrate layer and depositing an inter-level-dielectric (ILD) layer on top of the substrate layer.

10. The method of claim 9, wherein forming the nTSV further comprising forming an nTSV opening through the ILD layer and the substrate layer to expose a bottom portion of the at least one BPR, via a patterning process, and filling the nTSV opening with one or more conductive materials to form the nTSV.

11. The method of claim 7, wherein laterally widening the first recesses comprises wet etching the first recesses to form the enlarged deep STI regions that have a sigma shape or a hexagon shape, and that have a first width at near a top thereof and a second width at near a middle portion thereof with the second width being larger than the first width.

12. The method of claim 7, further comprising, before forming the first recesses in the semiconductor substrate, forming a plurality of fin-sets on top of the semiconductor substrate including fin-sets for p-type field-effect-transistors (FETs) and fin-sets for n-type FETs, wherein the first recesses are formed between two fin-sets for a same type of FET.

13. The method of claim 12, further comprising forming the p-type FETs and the n-type FETs and forming a via-to-BPR contact to connecting the at least one BPR to at least one of the p-type FETs and the n-type FETs.

14. The method of claim 13, further comprising forming a middle-of-line (MOL) layer over the p-type and n-type FETs, back-end-of-line (BEOL) layers over the MOL layer, and wafer bonding a carrier wafer onto a top of the BEOL layers.

15. A semiconductor structure comprising:
a substrate layer; and
a plurality of buried power rails (BPRs) embedded in a plurality of laterally enlarged deep shallow-trench-isolation (STI) regions inside the substrate layer, wherein the plurality of BPRs is isolated from the substrate layer, respectively, by the plurality of laterally enlarged deep STI regions.

16. The semiconductor structure of claim 15, further comprising a plurality of through-silicon vias (TSVs) formed in the substrate layer, wherein a bottom portion of the TSVs contacting a bottom portion of the BPRs, wherein the bottom portion of the TSVs is fully surrounded by the laterally enlarged deep STI regions.

17. The semiconductor structure of claim 16, wherein the plurality of TSVs is embedded in the substrate layer and sidewalls of the plurality of TSVs are fully surrounded by and isolated from the substrate layer by the laterally enlarged deep STI regions.

18. The semiconductor structure of claim 17, wherein the laterally enlarged deep STI regions comprise flowable oxide, the plurality of TSV comprises one or more metal elements of W, Co, Ru, and Cu, and wherein the flowable oxide of the laterally enlarged deep STI regions directly contact the metal element of the plurality of TSVs at sidewalls thereof.

19. The semiconductor structure of claim 16, wherein at least one of the TSVs is misaligned with at least one of the BPRs, a first part of a bottom portion of the at least one of the TSVs contacts a bottom portion of the at least one of the BPRs, and a second part of the bottom portion of the at least one of the TSVs is covered by one of the laterally enlarged deep STI regions.

20. The semiconductor structure of claim 15, wherein the laterally enlarged deep STI regions have a first width at near a top thereof and a second width at near a middle portion thereof, wherein the second width being larger than the first width.
